(19) United States
(12) Patent Application Publication
(10) Pub. No.: US 2008/0111139 A1
(43) Pub. Date: May 15, 2008

(54) Vertical light emitting device and method of manufacturing the same

(75) Inventors: Jung-hye Chae, Seoul (KR); Myoung-gyun Suh, Pohang (KR)

Correspondence Address: HARNESS, DICKEY & PIERCE, P.L.C., P.O. BOX 8910, RESTON, VA, 20195, US

(73) Assignee: Samsung Electro-Mechanics Company Ltd.

(21) Appl. No.: 11/878,348

(22) Filed: Jul. 24, 2007

(30) Foreign Application Priority Data
Nov. 14, 2006 (KR) 10-2006-0112450

(51) Int. Cl. H01L 33/00

(52) U.S. Cl. 257/79; 438/39; 257/E33.006

(57) ABSTRACT

Provided is a vertical light emitting device having improved light extraction efficiency and a method of manufacturing the same. The vertical light emitting device may include a p type electrode, a p type semiconductor layer, an active layer, and an n type semiconductor layer which may be sequentially formed on the p type electrode, and an n type electrode on a portion of a surface of the n type semiconductor layer, wherein the portion of the surface of the n type semiconductor layer may be at an inclined plane inclined from an area near a circumference of the n type electrode towards the active layer. The p type electrode may include a current blocking layer which is made of an insulating material and on the p type electrode directly under the n type electrode. Accordingly, a voltage increase may be minimized or reduced, and light extraction efficiency may be improved.

### PRIORITY STATEMENT

This application claims priority under 35 U.S.C. §119 to Korean Patent Application No. 10-2006-0112450, filed on Nov. 14, 2006, in the Korean Intellectual Property Office (KIPO), the entire contents of which are incorporated herein by reference.

### BACKGROUND

1. Field

Example embodiments relate to a vertical light emitting device and a method of manufacturing the same. Other example embodiments relate to a vertical light emitting device having improved light extraction efficiency and a method of manufacturing the same.

2. Description of the Related Art

Light emitting devices, for example, light emitting diodes (LEDs), may be applied to communication fields, e.g., optical communication fields and a backlight for relatively large-sized electrical signs and liquid crystal display devices. LEDs formed of Groups III-V compound semiconductors may be used and research has been conducted to improve the light extraction efficiency of LEDs.

FIG. 1 is a view illustrating a conventional vertical light emitting device 10.

Referring to FIG. 1, the vertical light emitting device 10 may include a p type electrode 11, a p type semiconductor layer 12, an active layer 13 and an n type semiconductor layer 14 which are sequentially stacked. An n type electrode 15 may be electrically connected to a portion of the surface of the n type semiconductor layer 14.

When a voltage is applied between the p type electrode 11 and the n type electrode 15, electrons may be injected from the n type electrode 15 to the n type semiconductor layer 14 and holes may be injected from the p type electrode 11 to the p type semiconductor layer 12 along current paths indicated by dotted lines in FIG. 1. When the electrons and the holes are combined in the active layer 13, light may be emitted. The emitted light may be partially reflected and partially absorbed by the n type semiconductor layer 14. The reflected light may be multiple-reflected or radiated toward the outside of the n type electrode 15. The electrons and the holes may be mainly combined in a portion of the active layer 13 located directly under the n type electrode 15, that is, an area marked by A in FIG. 1. Thus, the light may be generated from the A area. However, when the light generated from the A area passes through the n type semiconductor layer 14 to be radiated to the outside, a portion of the light may be blocked by the n type electrode 15. The n type electrode 15 may be formed of Ti/Al. Because the reflectivity of Ti/Al is relatively small, for example, about 40%, optical loss may be relatively great. Accordingly, the emitting device 10 of FIG. 1 may not have desirable light extraction efficiency.

FIG. 2 illustrates another conventional vertical light emitting device 20 which has improved light extraction efficiency due to the use of a current blocking layer (CBL) 27. Referring to FIG. 2, the vertical light emitting device 20 may include a p type electrode 21, a p type semiconductor layer 22, an active layer 23, an n type semiconductor layer 24 and an n type electrode 25 which are sequentially stacked. The structure of the vertical light emitting device 20 may be basically the same as the structure of the emitting device 10 of FIG. 1.

However, the emitting device 20 may further include the CBL 27 formed in the p type electrode 21. The CBL 27 may be formed in the p type electrode 21 and located directly under the n type electrode 21. The diameter of the CBL 27 may be about the same as that of the n type electrode 21.

When the CBL 27 is formed in the p type electrode 21, current paths may be formed as indicated by dotted lines in FIG. 2. Accordingly, an area A′, where electrons and holes are combined, may exceed an area located directly under the n type electrode 25. Thus, light generated from the area A′ may be blocked by the n type electrode 25 at a relatively low rate. Therefore, the light extraction efficiency of the emitting device 20 may be greater than that of the emitting device 10 of FIG. 1.

However, when the current density around the CBL 27 in the emitting device 20 is increased, current may accumulate around the CBL 27. This current crowding phenomenon may deteriorate the reliability of the emitting device 20. In addition, because a driving voltage of the emitting device 20 is increased by the CBL 27, the characteristic of luminous efficiency versus power consumption may be decreased.

### SUMMARY

Example embodiments provide a vertical light emitting device which has increased light extraction efficiency by minimizing or reducing a voltage increase due to a current blocking layer (CBL) and a method of manufacturing the same.

According to example embodiments, a vertical light emitting device may include a p type electrode, a p type semiconductor layer, an active layer, and an n type semiconductor layer on the p type electrode, respectively, and an n type electrode on a portion of a surface of the n type semiconductor layer, wherein the portion of the surface of the n type semiconductor layer may be at an inclined plane inclined from an area near a circumference of the n type electrode towards the active layer.

According to example embodiments, a method of manufacturing a vertical light emitting device may include providing a p type electrode, forming a p type semiconductor layer, an active layer, and an n type semiconductor layer on the p type electrode, respectively, and forming an n type electrode on a portion of a surface of the n type semiconductor layer, wherein the portion of the surface of the n type semiconductor layer may be at an inclined plane from an area near a circumference of the n type electrode towards the active layer.

An angle of inclination of the inclined plane may be about 75 degrees or less. An angle of inclination of the inclined plane may be about 10 degrees-about 40 degrees. A vertical height of the inclined plane may be about 2 μm or more. A vertical height of the inclined plane may be about 2 μm-about 3 μm.

The p type electrode may include a current blocking layer which may be formed of an insulating material and formed on the p type electrode directly under the n type electrode. The current blocking layer may be formed of silicon oxide. A diameter of the current blocking layer may be smaller than a diameter of the n type electrode. The diameter of the current blocking layer may be about 50%-about 90% of the diameter of the n type electrode. The diameter of the current blocking layer may be about 50%-about 80% of the diameter of the n type electrode.

### BRIEF DESCRIPTION OF THE DRAWINGS

Example embodiments will be more clearly understood from the following detailed description taken in conjunction with the accompanying drawings. FIGS. 1-8 represent non-limiting, example embodiments as described herein.

FIG. 1 is a view illustrating a conventional vertical light emitting device;

FIG. 2 shows another conventional vertical light emitting device having high light extraction efficiency due to the use of a current blocking layer (CBL);

FIG. 3 is a cross-sectional view illustrating a vertical light emitting device according to example embodiments;

FIG. 4 is a cross-sectional view illustrating a vertical light emitting device according to example embodiments;

FIG. 5 is a graph of current versus voltage for comparing a light emitting device according to example embodiments with a conventional emitting device;

FIG. 6 is a graph of dynamic resistance and voltage versus diameter of the CBL when a current is maintained constant, for comparing a light emitting device according to example embodiments with a conventional emitting device;

FIG. 7 is a graph of optical power versus diameter of a CBL for comparing a light emitting device according to example embodiments with a conventional emitting device; and

FIG. 8 is a graph showing improvement of light extraction efficiency versus diameter of a CBL for comparing a light emitting device according to example embodiments with a conventional emitting device.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. In particular, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully with reference to the accompanying drawings, in which example embodiments are shown. Example embodiments may, however, be embodied in many different forms and should not be construed as being limited to the embodiments set forth herein. Rather, these embodiments are provided so that this disclosure will be thorough and complete, and will fully convey the concept of example embodiments to those skilled in the art. In the drawings, the thicknesses of layers and regions are exaggerated for clarity. Like numbers refer to like elements throughout the specification.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

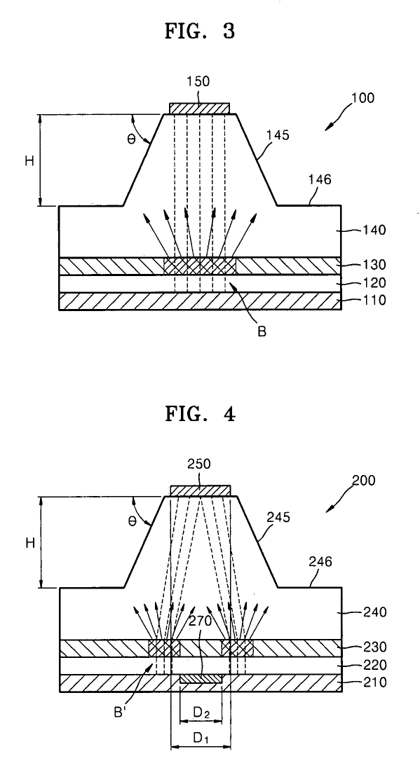

FIG. 3 is a cross-sectional view illustrating a vertical light emitting device 100 according to example embodiments. Referring to FIG. 3, the vertical light emitting device 100 may include a p type electrode 110, a p type semiconductor layer 120, an active layer 130 and an n type semiconductor layer 140 which are sequentially formed on the p type electrode 110. An n type electrode 150 may be formed on a portion of a surface of the n type semiconductor layer 140.

The p type semiconductor layer 120 may be a p type material layer formed of GaN based Groups III-V nitride compounds, and may be a direct transition type layer doped with p type conductive material, for example, a p-GaN layer. The p type semiconductor layer 120 may be a material layer including GaN based Groups III-V nitride compounds and aluminum (Al) or indium (In) in a predetermined or given ratio, for example, an AlGaN and/or InGaN layer.

The n type semiconductor layer 140 may be an n type material layer formed of GaN based Groups III-V nitride compounds, for example, an n-GaN layer. The n type semiconductor layer 140 may be a material layer including GaN based Groups III-V nitride compounds and aluminum (Al) or indium (In) in a predetermined or given ratio, for example, an AlGaN and/or InGaN layer.

The active layer 130 may be a material layer which emits light by a combination between carriers, e.g., electrons and holes, and may be formed of GaN based Groups III-V nitride compounds having a multi quantum well (MQW) structure, for example, an InₓAl_{y}Ga_{1-x-y}N (0≦x≦1, 0≦y≦1 and x+y≦1) layer. The active layer 130 may be a material layer including GaN based Groups III-V nitride compounds and indium (In) in a predetermined or given ratio, for example, an InGaN layer.

The p type electrode 110 may function as a reflective layer for reflecting light. The p type electrode 110 may be formed of a metal, e.g., Ni/Ag and/or Ru, having reflectivity of about 85%. The n type electrode 150 may be formed of a metal, e.g., Ti/Al, having reflectivity of about 40%. The materials of the p type semiconductor layer 120, the active layer 130, the n type semiconductor layer 140, the p type electrode 110 and the n type electrode 150 may not be limited to the above described.

In the emitting device 100 having the above structure, an electron may be injected through the n type electrode 150 to the n type semiconductor layer 140, and a hole may be injected through the p type electrode 110 to the p type semiconductor layer 120. The injected electron and hole may be combined in the active layer 130, thereby emitting light. The electron and the hole may be mainly combined in a portion of the active layer 130 located directly under the n type electrode 150, for example, an area marked by B in FIG. 3. Light generated from the B area of the active layer 130 or other areas proceeds in various directions into the n type semiconductor layer 140.

As described above, a portion of the light, which is generated from the active layer 130 and goes through the n type semiconductor layer 140 to be radiated to the outside, may be completely reflected at an interface between the n type semiconductor layer 140 and the n type electrode 150, and a surface of the n type semiconductor layer 140 according to a radiation angle. For example, when the light is incident on the interface between the n type semiconductor layer 140 and the n type electrode 150, and on the surface of the n type semiconductor layer 140 at an angle greater than a critical angle at which light is completely reflected, the light may be completely reflected. When the completely reflected light is repeatedly reflected among the interface between the n type semiconductor layer 140 and the n type electrode 150 and the surface of the n type semiconductor layer 140 and the p type electrode 110, light energy may be reduced, and thus, light extraction efficiency may also be reduced.

In example embodiments, in order to minimize or reduce the completely reflected light to increase the light extraction efficiency, a portion of the surface of the n type semiconductor layer 140 may be formed as an inclined plane 145 from an area near the circumference of the n type electrode 150 towards the active layer 130. For example, the inclined plane 145 of the n type semiconductor layer 140 may be formed by etching the surface of the n type semiconductor layer 140 to a predetermined or given depth. An angle of inclination Θ and a vertical height H of the inclined plane 145 may be variously determined. However, the angle of inclination Θ may be about 75 degrees or less with respect to a horizontal plane 146, for example, about 10 degrees-about 40 degrees. The vertical height H of the inclined plane 145 may be about 2 μm or more, for example, about 2 μm-about 3 μm. Accordingly, the surface of the n type semiconductor layer 140 may include the inclined plane 145 and the horizontal plane 146.

In the emitting device 100 having the above the light, which is generated from the active layer 130 and proceeds in various directions, may be incident on the interface between the n type electrode 150 and the n type semiconductor layer 140, the inclined plane 145 of the n type semiconductor layer 140 and the horizontal plane 146. When the light is incident at an angle smaller than a critical angle at which light is completely reflected, the light may be extracted to the outside. When the light is incident at an angle greater than the critical angle, the light may be completely reflected. Even though the light is completely reflected on the horizontal plane 146, because the light is incident at an angle smaller than a critical angle, the light may be extracted to the outside. At least a portion of the light, which is completely reflected on the interface between the n type electrode 150 and the n type semiconductor layer 140, may be extracted through the inclined plane 145 to the outside.

As described above, in the emitting device 100, because the inclined plane 145 is formed on the surface of the n type semiconductor layer 140, the light incident at various angles may be extracted, and thus the light extraction efficiency may be increased compared with the conventional art.

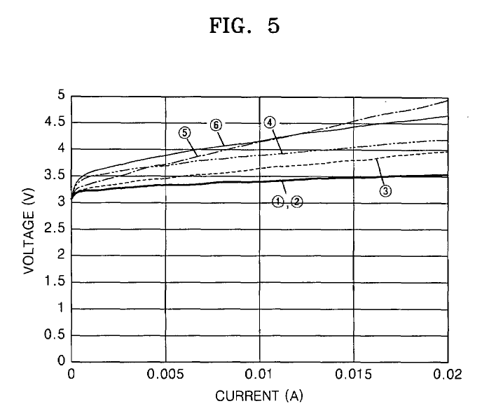

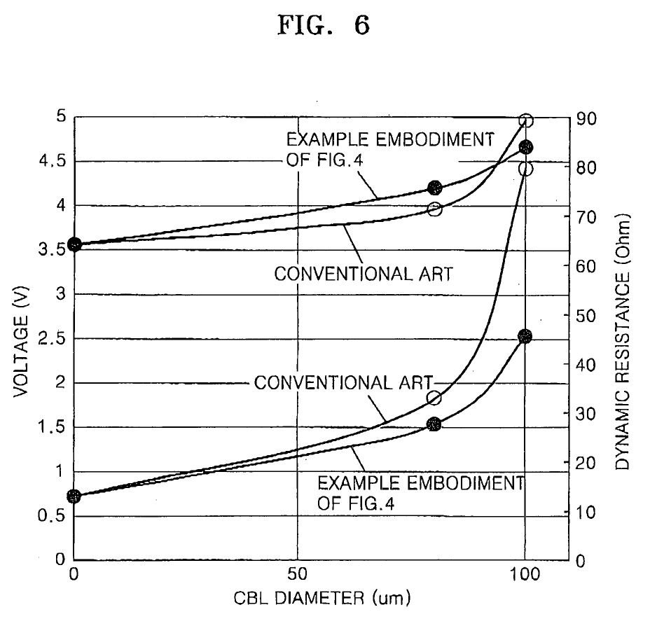

FIG. 4 is a cross-sectional view illustrating a vertical light emitting device 200 according to example embodiments. Referring to FIG. 4, the vertical light emitting device 200 may include a p type electrode 210, a p type semiconductor layer 220, an active layer 230 and an n type semiconductor layer 240 which are sequentially stacked on the p type electrode 210. An n type electrode 250 may be formed on a portion of a surface of the n type semiconductor layer 240.

In order to improve light extraction efficiency, the surface of the n type semiconductor layer 240 may include an inclined plane 245 from an area near the circumference of the n type electrode 250 towards the active layer 230, and a horizontal plane 246. An angle of inclination Θ of the inclined plane 245 may be about 75 degrees or less, for example, about 40 degrees-about 10 degrees. A vertical height H of the inclined plane 245 may be about 2 μm or more, for example, about 2 μm-about 3 μm. The structure of the vertical light emitting device 200 may be basically the same as the structure of the emitting device 100 of FIG. 3, and thus detailed descriptions of the emitting device 200 will be omitted.

The vertical light emitting device 200 may further include a current blocking layer (CBL) 270 formed in the p type electrode 210. For example, the CBL 270 may be formed in the p type electrode 110 so as to be located directly under the n type electrode 210. The CBL 270 may be formed of an insulating material, for example, silicon oxide (SiO₂). The diameter D₂ of the CBL 270 may be smaller than the diameter D₁ of the n type electrode 250. The diameter D₂Of the CBL 270 may be about 50%-about 90% of the diameter D₁ of the n type electrode 250, for example, about 50%-about 80% of the diameter D₁ of the n type electrode 250.

As described above, when the CBL 270 is formed in the p type electrode 210, current paths may be formed as indicated by dotted lines in FIG. 4. Accordingly, an area B′, where electrons and holes are combined, may exceed an area located directly under the n type electrode 250. Light generated from the area B′ may proceed in various directions in the n type semiconductor layer 240 and may reach an interface between the n type electrode 250 and the n type semiconductor layer 240, and the inclined plane 245 and the horizontal plane 246 of the n type semiconductor layer 240. The light blocked by the n type electrode 250 may be relatively low. Because the light, which may be incident at various angles due to the inclined plane 245 formed on the surface of the n type semiconductor layer 240, is extracted, light extraction efficiency may be increased.

In the vertical light emitting device 200, the diameter D₂ of the CBL 270 may be smaller than the diameter D₁ of the n type electrode 250. Thus, a voltage increase due to the CBL 270 may be minimized or reduced, and a current crowding phenomenon generated by the increased current density around the CBL 270 may be reduced. This will be described later.

FIG. 5 is a graph of current versus voltage for comparing the light emitting devices according to example embodiments with a conventional emitting device.

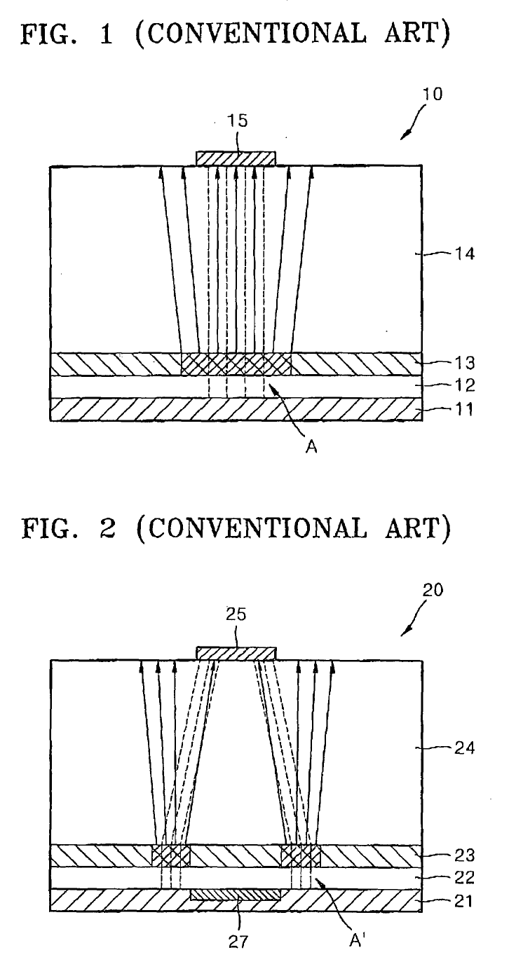

Referring to FIG. 5, line 1 corresponds to the light emitting device 100 of FIG. 3 which has an inclined plane and no CBL, line 2 corresponds to the light emitting device 10 of FIG. 1 which has no CBL and no inclined plane, line 3 corresponds to a light emitting device which has no inclined plane and has a CBL having a diameter smaller than that of an n type electrode, line 4 corresponds to the light emitting device 200 of FIG. 4 which has an inclined plane and a CBL having a smaller diameter than that of an n type electrode, line 5 corresponds to the conventional emitting device 20 FIG. 2 which has no inclined plane and has a CBL having the same diameter as that of an n type electrode, and line 6 corresponds to an emitting device which has an inclined plane and a CBL having the same diameter as that of an n type electrode.

Referring FIG. 5, when the light emitting device has no CBL (lines 1 and 2), the current versus voltage graph may be the same. When the light emitting device has a CBL having a smaller diameter than that of an n type electrode (lines 3 and 4), the voltage of the light emitting device having an inclined plane (line 4) may be higher than that of the light emitting device having no inclined plane (line 3). In addition, the voltage of the light emitting device having a CBL having a smaller diameter than an n type electrode (lines 3 and 4) may be smaller than that of the light emitting device having the same diameter as that of an n type electrode (lines 5 and 6).

As described above, FIG. 5 illustrates that an inclined plane formed in an emitting device according to example embodiments affects a voltage increase, but the voltage increase may be minimized or reduced when the emitting device 200 of FIG. 4 has a CBL having a smaller diameter than that of an n type electrode.

FIG. 6 is a graph of dynamic resistance and voltage versus diameter of the CBL when a current is maintained at about 20 mA, for comparing an emitting device according to example embodiments with a conventional emitting device. Two bottom lines show the dynamic resistance, and two upper lines show the voltage. The diameter of the CBL may be shown as a percentage with respect to the diameter of an n type electrode.

Referring to FIG. 6, the voltage and dynamic resistance may increase as the diameter of the CBL is greater in both the emitting device according to example embodiments and the conventional emitting device. For example, the voltage and the dynamic resistance may be remarkably increased when the diameter of a CBL is about 90% of that of an n type electrode. Where a light emitting device having a CBL having a diameter of about 80% or less of that of an n type electrode, voltage and dynamic resistance differences between the emitting device according to example embodiments and the conventional emitting device may be relatively small.

Accordingly, in the emitting device 200 of FIG. 4, the diameter of a CBL may be about 90% of that of a CBL or less, for example, about 80% of that of the n type electrode or less.

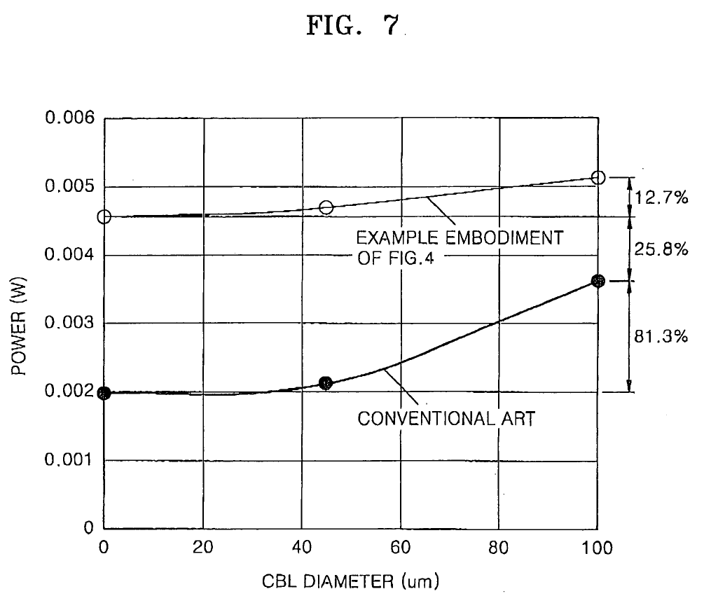

FIG. 7 is a graph of optical power versus diameter of a CBL for comparing a light emitting device according to example embodiments with a conventional emitting device. In FIG. 7, the diameter of the CBL may be shown as a percentage with respect to the diameter of an n type electrode. Referring to FIG. 7, the optical power of the emitting device having an inclined plane according to example embodiments may be higher than that of the conventional emitting device.

With regard to the conventional art, the optical power of a light emitting device may have the CBL having the same diameter as that of the n type electrode and may be increased by about 81.3% of the optical power of the light emitting device having no CBL. For example, the optical power may be remarkably increased when the diameter of the CBL is about 50% of that of the n type electrode or more.

With regard to example embodiments, the optical power of the light emitting device having no CBL may be increased by about 25.8% of the optical power of the conventional light emitting device having the CBL. In the emitting device according to example embodiments, the optical power may start increasing when the diameter of the CBL is about 50% of that of the n type electrode or more, and the optical power may be increased by about 12.7% of the optical power of the light emitting device having no CBL when the diameter of the CBL is the same as that of the n type electrode.

Accordingly, the optical power of the light emitting device having an inclined plane according to example embodiments may be higher than the optical power of the conventional emitting device. In addition, light extraction efficiency may be increased more when the light emitting device further includes the CBL. In order to improve light extraction efficiency, the diameter of the CBL may be about 50% of that of an n type electrode or more.

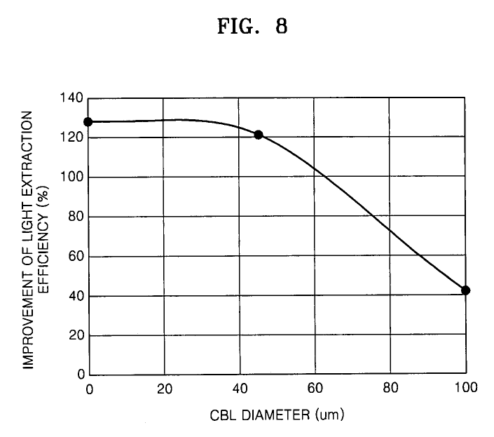

FIG. 8 is a graph showing improvement of light extraction efficiency versus the diameter of a CBL when comparing a light emitting device according to example embodiments with a conventional emitting device. The diameter of the CBL may be shown as a percentage with respect to the diameter of an n type electrode.

Referring to FIG. 8, the light extraction efficiency of the emitting device according to example embodiments may be improved by about 130% of that of the conventional emitting device until the diameter of the CBL may be about 40% of the n type electrode. Improvement of light extraction efficiency may be gradually lowered when the diameter of the CBL is more than about 40% of the n type electrode.

As described above, because a portion of a surface of an n type electrode layer is formed as an inclined plane, light extraction efficiency may be improved. When the CBL is not formed on the p type electrode, light extraction efficiency may be improved and voltage may not be increased.

Because a voltage increase may be minimized or reduced and light extraction efficiency may be improved when the CBL, which has a smaller diameter than that of the n type electrode and formed on the p type electrode in addition to the inclined plane, is included in a light emission device according to example embodiments, luminous efficiency may be improved.

While example embodiments have been particularly shown and described with reference to example embodiments thereof, it will be understood by those of ordinary skill in the art that various changes in form and details may be made therein without departing from the spirit and scope of the following claims.

What is claimed is:

1. A vertical light emitting device comprising:
a p type electrode;
a p type semiconductor layer, an active layer, and an n type semiconductor layer on the p type electrode, respectively; and
an n type electrode on a portion of a surface of the n type semiconductor layer,
wherein the portion of the surface of the n type semiconductor layer is at an inclined plane from an area near a circumference of the n type electrode towards the active layer.

2. The vertical light emitting device of claim 1, wherein an angle of inclination of the inclined plane is about 75 degrees or less.

3. The vertical light emitting device of claim 2, wherein an angle of inclination of the inclined plane is about 10 degrees-about 40 degrees.

4. The vertical light emitting device of claim 1, wherein a vertical height of the inclined plane is about 2 μm or more.

5. The vertical light emitting device of claim 4, wherein a vertical height of the inclined plane is about 2 μm-about 3 μm.

6. The vertical light emitting device of claim 1, wherein the p type electrode includes a current blocking layer (CBL) which is made of an insulating material and formed on the p type electrode directly under the n type electrode.

7. The vertical light emitting device of claim 6, wherein the current blocking layer is formed of silicon oxide.

8. The vertical light emitting device of claim 6, wherein a diameter of the current blocking layer is smaller than a diameter of the n type electrode.

9. The vertical light emitting device of claim 8, wherein the diameter of the current blocking layer is about 50%-about 90% of the diameter of the n type electrode.

10. The vertical light emitting device of claim 9, wherein the diameter of the current blocking layer is about 50%-about 80% of the diameter of the n type electrode.

11. A method of manufacturing a vertical light emitting device comprising:
providing a p type electrode;
forming a p type semiconductor layer, an active layer, and an n type semiconductor layer on the p type electrode, respectively; and
forming an n type electrode on a portion of a surface of the n type semiconductor layer,
wherein the portion of the surface of the n type semiconductor layer is at an inclined plane from an area near a circumference of the n type electrode towards the active layer.

12. The method of claim 11, wherein an angle of inclination of the inclined plane is about 75 degrees or less.

13. The method of claim 12, wherein an angle of inclination of the inclined plane is about 10 degrees-about 40 degrees.

14. The method of claim 11, wherein a vertical height of the inclined plane is about 2 μm or more.

15. The method of claim 14, wherein a vertical height of the inclined plane is about 2 μm-about 3 μm.

16. The method of claim 11, wherein forming the p type electrode includes forming a current blocking layer (CBL) which is made of an insulating material and on the p type electrode directly under the n type electrode.

17. The method of claim 16, wherein forming the current blocking layer includes forming the current blocking layer of silicon oxide.

18. The method of claim 16, wherein a diameter of the current blocking layer is smaller than a diameter of the n type electrode.

19. The method of claim 18, wherein the diameter of the current blocking layer is about 50%-about 90% of the diameter of the n type electrode.

20. The method of claim 19, wherein the diameter of the current blocking layer is about 50%-about 80% of the diameter of the n type electrode.
